(19) United States
(12) Patent Application Publication
(10) Pub. No.: US 2024/0392735 A1
(43) Pub. Date: Nov. 28, 2024

(54) Microfabricated Multiemitter Electrospray Thrusters

(71) Applicant: The Regents of the University of California, Oakland, CA (US)

(72) Inventors: Manuel Gamero-Castaño, Irvine, CA (US); Albert Cisquella-Serra, Irvine, CA (US); Marc Galobardes-Esteban, Irvine, CA (US)

(21) Appl. No.: 18/688,600

(22) PCT Filed: Sep. 2, 2022
(86) PCT No.: PCT/US22/42468

§ 371 Date: Mar. 1, 2024

Related U.S. Application Data
(60) Provisional application No. 63/240,738, filed on Sep. 3, 2021.

(51) Int. Cl. F02K 9/52

(52) U.S. Cl. CPC F02K 9/52

(57) ABSTRACT

Microfabricated multiemitter electrospray thrusters in accordance with embodiments of the invention are disclosed. In one embodiment, an electrospray thruster for electrospraying at least one liquid propellant is provided, the electrospray thruster comprising: an emitter electrode comprising a backside comprising at least one microfluidic channel, wherein the at least one microfluidic channel provides hydraulic impedance to flow of the at least one liquid propellant, and a front side comprising an emitter array comprising at least one emitter, wherein the at least one emitter comprises an inner channel and an emitter tip: wherein the at least one liquid propellant reaches the emitter tip through the inner channel; and wherein each channel of the at least one microfluidic channel feeds the at least one liquid propellant to the at least one emitter via a hole connecting the at least one microfluidic channel with the inner channel of the at least one emitter.

### FEDERAL FUNDING SUPPORT

This invention was made with Government support under Grant No. 80NSSC20M0084, awarded by the National Aeronautics and Space Administration. The Government has certain rights in the invention.

### FIELD OF THE INVENTION

The present invention generally relates to propulsion systems and more specifically to microfabricated multiemitter electrospray thrusters. The present invention has applications in various other fields such as, but not limited to, mass spectrometry, deposition of coatings, surface engineering and electrospinning.

### BACKGROUND

With the decreasing service price of commercial rocket launchers and the downsizing of satellites (e.g., satellites with mass below 200 kg (“SmallSats”)), space technology activity has significantly increased. For example, during the first ten months of 2020, 1079 satellites have been launched worldwide, 1029 of which were SmallSats. In comparison, in 2019, 385 SmallSats were launched. The SmallSat industry is becoming the path to space capabilities for many entities such as, but not limited to, small companies, countries, and worldwide research groups that may have previously been out of reach due to cost limitations.

### SUMMARY OF THE INVENTION

The various embodiments of the present microfabricated multiemitter electrospray thrusters (may also be referred to as “electrospray thrusters”) contain several features, no single one of which is solely responsible for their desirable attributes. Without limiting the scope of the present embodiments, their more prominent features will now be discussed below. In particular, the present electrospray thrusters will be discussed in the context of propulsion systems for SmallSats. However, the use of propulsion systems for SmallSats is merely exemplary and various other satellites, devices, systems, etc. may be utilized for use with the present electrospray thrusters as appropriate to the requirements of a specific application in accordance with various embodiments of the invention. Further, the present electrospray thrusters will be discussed in the context of particular emitter arrays (may also be referred to as “emitter” or “emitter electrode”) (e.g., 1-emitter electrode, 64-emitter electrode, 256-emitter electrode, etc.) having specific number, size, and/or configuration of microchannels. However, the use of particular emitter arrays and/or particular microchannels are also merely exemplary and various other emitter arrays and/or microchannels may be utilized for electrospray thrusters as appropriate to the requirements of a specific application in accordance with various embodiments of the invention. After considering this discussion, and particularly after reading the section entitled “Detailed Description,” one will understand how the features of the present embodiments provide the advantages described here.

One aspect of the present embodiments includes the realization that a potential downside in the capabilities of SmallSats may be the lack of efficient propulsion systems. For example, a propulsion system integrated into SmallSats should have a small volume, low mass, low power requirements, and high efficiency. Such capable propulsion systems could change the use of SmallSats and various other satellites, such as, but not limited to NanoSats (satellites with a mass below 10 Kg), enabling space exploration missions, long-life commercial applications, and/or constellations of satellites. Some other tasks that may be achieved by adding a propulsion system into SmallSats may include precise attitude control, atmospheric drag compensation, controlled deorbiting, maneuvers to avoid orbital debris impact and orbit transfers (e.g., from low earth orbit (“LEO”), to medium earth orbit (“MEO”) or even geosynchronous orbit (“GEO”)).

Another aspect of the present embodiments includes the realization that development of an optimal propulsion system is a complex engineering effort. For example, a propulsion system may have a lot of interfaces to be integrated into different subsystems without compromising the spacecraft performance, design, and cost. Further, a propulsion system typically needs to go through a long process of verification and validation before operating in space. A consideration for SmallSat propulsion is the choice between chemical or electrical propulsion. Chemical propulsion systems may use a considerable amount of propellant to achieve typical delta-V maneuver, due to their relatively low exhaust velocities (low-moderate specific impulse). Furthermore, traditional chemical propulsion systems may be difficult to downsize to the level of SmallSats or smaller. Electric propulsion systems typically operate with specific impulses one order of magnitude higher than chemical propulsion, reducing significantly the amount of propellant needed for a maneuver with a given delta-V.

Another aspect of the present embodiments includes the realization that electrospray propulsion is based on the electrostatic acceleration of charged droplets and ions produced by the electrospraying of a liquid propellant. An electrospray emitter may operate at power levels of a few milli-watts with efficiencies above 70%. This is unique among electric propulsion technologies (other electric propulsion technologies include ions engines, Hall thrusters, etc.), which cannot operate at such low power levels with the required efficiency. Since an electric propulsion system for a SmallSat may operate at power levels between a few and several tens of Watts (this is typically the amount of power that SmallSats can be harvested from the sun through solar cells), and most electric propulsion technologies cannot operate at these power levels efficiently, the proposed electrospray thrusters are an enabling propulsion technology for SmallSats. To process these power levels, an array of electrospray emitters may be utilized and such arrays (e.g., arrays with thousands of emitters) may be possible by using micromachining techniques, as further described below.

Another aspect of the present embodiments includes the realization that having on-board propulsion may be a key to continue developing small satellites (e.g., SmallSats), which may be the spacecraft class that will dominate the commercial and scientific space market in the near future. Further, electric propulsion systems may be key for reasons including, but not limited to, savings in propellant mass. In addition, among electric propulsion technologies, micromachined electrospray thrusters is an ideal candidate from the point of view of efficiency at the typical power levels of SmallSats, propulsion system size considerations, and size/power scalability.

### BRIEF DESCRIPTION OF THE DRAWINGS

The various embodiments of the present microfabricated multiemitter electrospray thrusters now will be discussed in detail with an emphasis on highlighting the advantageous features. These embodiments depict the novel and non-obvious features of systems, methods, and devices for electrospray thrusters shown in the accompanying drawings, which are for illustrative purposes only. These drawings include the following figures:

FIG. 1A is a schematic diagram illustrating an electrospray thruster head in accordance with an embodiment of the invention.

FIG. 1B is a schematic diagram illustrating the electrospray thruster head after bonding the emitter, extractor, and platform wafers in accordance with an embodiment of the invention.

FIG. 2 is a schematic diagram illustrating a microfabrication process for an emitter array electrode in accordance with an embodiment of the invention.

FIG. 3 is a schematic diagram illustrating another microfabrication process for an emitter array electrode in accordance with an embodiment of the invention.

FIG. 4 is an optical image of fabricated microchannels for an 8×8 emitter array electrode in accordance with an embodiment of the invention.

FIG. 5 is a schematic diagram illustrating a microchannel for a 16×16 emitter array electrode in accordance with an embodiment of the invention.

FIGS. 6A-B illustrate a 64-emitter electrode having a front side with 64 emitters and a backside with flow resistive channels in accordance with an embodiment of the invention.

FIGS. 6C-D illustrate a 256-emitter electrode having a front side with 64 emitters and a backside with flow resistive channels in accordance with an embodiment of the invention.

FIGS. 7A-B illustrate fabrication step of emitters and surrounding well pattern on a SiO₂ layer in accordance with an embodiment of the invention.

FIG. 8A illustrates step fabrication of emitters partial inner channel before etching surrounding well in accordance with an embodiment of the invention.

FIG. 8B illustrates fabrication of emitters and surrounding well pattern after etching and stripping in accordance with an embodiment of the invention.

FIG. 9 illustrates results of etching of emitters electrodes in accordance with an embodiment of the invention.

FIGS. 10A-B are scanning electron microscope (“SEM”) images illustrating an etched emitter and pool in accordance with an embodiment of the invention.

FIGS. 11A-B are SEM images illustrating another etched emitter and pool in accordance with an embodiment of the invention.

FIGS. 12A-D are SEM images illustrating another etched emitter with different diameter and pool in accordance with an embodiment of the invention.

FIGS. 13A-D are optical images illustrating emitter inner etched channels matching ends of microchannels in accordance with an embodiment of the invention.

FIGS. 14A-B are SEM images illustrating an emitter inner etched channel matching an end of microchannels in accordance with an embodiment of the invention.

FIG. 15 illustrates shows silicon etched with XeF₂ dry isotropic etching to obtain high yield emitter tips in accordance with an embodiment of the invention.

FIG. 16 is a schematic diagram illustrating a microfabrication process for an extractor electrode (may also be referred to as an “extractor”) in accordance with an embodiment of the invention.

FIGS. 17A-D illustrate an extractor having a front with 64 and 256 holes and a back with an etch and frame for anodic bonding in accordance with an embodiment of the invention.

FIGS. 18A-B illustrate a borofloat glass wafer anodically bonded to a 64, with circumferences pointing to the location of orifices in the glass wafer, and 256-emitter electrode sealing flow-resistive microchannels in accordance with an embodiment of the invention.

FIG. 18C shows a test displaying absence of propellant leakage in the sealed network of microfluidic channels in accordance with an embodiment of the invention.

FIGS. 18D-E show the backside and front side view of a 64-emitter source (after bonding of the emitter, extractor and glass wafer) in accordance with an embodiment of the invention.

FIG. 18F shows a SEM image of the emitter/extractor region for one emitter in accordance with an embodiment of the invention.

FIGS. 18G-H show the backside and front side view of a 64-emitter source (after bonding of the emitter, extractor and glass wafer) in accordance with an embodiment of the invention.

FIG. 181 shows photographs focused on the emitter tips and extractor rims and their alignment in accordance with an embodiment of the invention.

FIGS. 19A-C show emitter and extractor current as a function using EMI-Im as propellant of pressure for the 256-emitter source, 64-emitter source and a single emitter source in accordance with an embodiment of the invention.

FIG. 19D shows the current and flow rate per emitter for the three sources in accordance with an embodiment of the invention.

FIG. 20A is a graph showing extractor current as a function of pressure using EMI-Im as propellant for the 256-emitter source in accordance with an embodiment of the invention.

FIG. 20B is a graph showing the variation of the current per emitter with emitter voltage using EMI-Im as propellant, for three different electrospray sources in accordance with an embodiment of the invention.

FIG. 20C is a graph showing emitter current as a function of emitter potential in accordance with an embodiment of the invention.

FIG. 21A is a graph showing a 64-emitter source without coating 42 hours performance test with current as a function of pressure in accordance with an embodiment of the invention.

FIGS. 21B-G show the evolution of the electrochemical film deposition that clogs the emitters in accordance with an embodiment of the invention.

FIG. 22A shows a 256-emitter electrode source with a 100 nm platinum coating on the front side without contamination on the backside (microchannels) in accordance with an embodiment of the invention.

FIG. 22B shows the backside of the coated 256-emitter array without platinum on it in accordance with an embodiment of the invention.

FIG. 22C shows the 256-emitter electrode source coated anodically bonded to the glass wafer in accordance with an embodiment of the invention.

FIG. 22D shows a SEM picture of an emitter coated with platinum in accordance with an embodiment of the invention.

FIG. 22E shows an EDX mapping of the emitter in accordance with an embodiment of the invention.

FIG. 22F shows a 64-emitter array electrode coated with platinum anodically bonded to a glass wafer in accordance with an embodiment of the invention.

FIG. 23A is a graph showing a 256-emitter source with a platinum coating 86 hours performance test with current as a function of pressure in accordance with an embodiment of the invention.

FIG. 23B is a graph showing two pressure current curves of the 256-emitter source performance test taken at the first day and last day of the test in accordance with an embodiment of the invention.

FIG. 24 is a graph showing emitter and extractor current as a function of pressure using EMI-DCA as propellant for a 64-emitter electrospray source in accordance with an embodiment of the invention.

FIG. 25 is a schematic diagram illustrating a process for the addition of an accelerator electrode in accordance with an embodiment of the invention.

FIG. 26 is another schematic diagram illustrating a process for the addition of an accelerator electrode in accordance with an embodiment of the invention.

### DETAILED DESCRIPTION OF THE DRAWINGS

The following detailed description describes the present embodiments with reference to the drawings. In the drawings, reference numbers of label elements of the present embodiments. These reference numbers are reproduced below in connection with the discussion of the corresponding drawing features.

Turning now to the drawings, microfabricated multiemitter electrospray thrusters are further described below. Design considerations and fabrication processes of electrospray thrusters for propulsion of SmallSats may address the various challenges and realizations described above. In many embodiments, micromachining techniques may be utilized to fabricate a compact electrospray source (e.g., an electrospray thruster head), with very low mass, that may process the electric power that can be delivered by a SmallSat. In various embodiments, the electrospray thrusters may convert such power into jet kinetic power (and hence thrust) with an efficiency significantly higher than existing electric propulsion technologies. In several embodiments, the propellant used may be a liquid which may not need to be stored at high pressures. Furthermore, the micromachining techniques used for fabricating the electrospray thruster head may allow for scalability to various sizes of satellites/vehicles including, but not limited to, SmallSats, larger spacecrafts, CubeSats, etc. For example, electrospray thrusters as described herein may be utilized for all sizes of SmallSats, may be suitable for larger spacecrafts, and suited for CubeSats. Further, the present embodiments of electrospray thrusters may be readily scalable for larger SmallSats, and may be used for larger spacecrafts (e.g., spacecrafts with masses over approximately 500 kg). Electrospray thruster heads in accordance with embodiments of the invention are further discussed below.

### Electrospray Thruster Heads

Typically, an electrospray thruster may include a thruster head having one or more electrodes. For example, in many embodiments, an electrospray thruster head may include an emitter array and an extractor (may also be referred to as an “emitter electrode” and an “extractor electrode,” respectively). In some embodiments, the electrospray thruster heads may have additional electrodes such as, but not limited to, an accelerator electrode downstream of the extractor to increase the exhaust velocity of a propellant.

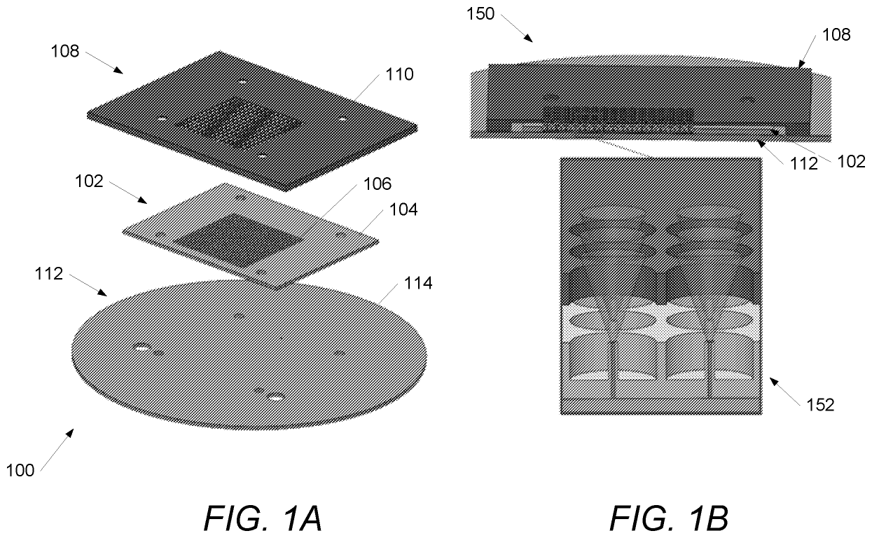

Schematic diagrams illustrating an electrospray thruster head in accordance with an embodiment of the invention are illustrated in FIGS. 1A-B. In many embodiments, an electrospray thruster head 100 may be microfabricated using three main components as shown in FIG. 1A. The electrospray thruster head 100 may include an emitter electrode 102 comprising a wafer 104 (e.g., a patterned double-polished Si wafer) (may also be referred to as an “emitter wafer”) with emitters 106 etched on a top side (may also be referred to as a “front side”) and microfluidic channels etched on a bottom side (may also be referred to as a “backside”), as further described below. Further, the electrospray thruster head 100 may include an extractor electrode 108 comprising a wafer 110 (e.g., a micromachined double-polished Si wafer) (may also be referred to as an “extractor wafer”), as further described below. In addition, the electrospray thruster head 100 may include a platform 112 comprising a wafer 114 (e.g., a borofloat or borosilicate glass wafer) (may also be referred to as a “platform wafer”) that may be configured to bond, align, and/or feed a propellant and seal the pool of propellant formed on the bottom side of the emitter wafer 102.

An electrospray propulsion system may include a spray source (e.g., an electrospray thruster head) and a spray. A schematic diagram illustrating the electrospray thruster head 150 after bonding the emitter 102, extractor 108, and platform 114 wafers together in accordance with an embodiment of the invention are illustrated in FIG. 1B. A zoomed in close up 152 is also provided in FIG. 1B. As further described below, advancements in design, fabrication, and operation of electrospray thruster heads described herein may include the addition of etched microchannels on the backside of the emitter array electrode 102 to increase the hydraulic resistance in the internally fed arrays, detached from the geometry and fabrication of the tubular emitters. The width, depth, and length of the microchannels may be readily modified to provide the optimal hydraulic resistance for each emitter. Further, the microfabrication processes described herein may allow for the design, fabrication and operation of electrospray thruster heads with different emitter diameters, emitter densities, and different distances between the emitter array electrode and the extractor electrode to fit the thrust and power requirements of an end-user. Moreover, the integration, high precision alignment, and bonding methods described herein of the three main components (i.e., the emitter 102, extractor 108, and platform 112 wafers) of the thruster head 100 through anodic bonding, may result in a compact thruster head. The alignment and bonding methods allows for additional components such as, but not limited to, an additional fourth component (i.e., a post accelerating grid, if necessary). Furthermore, an optimal operation of electrospray thruster heads may be configured using a pure ionic liquid, ionic liquid mixtures, ionic liquid-solvent mixtures, or any other liquid as propellant. In addition, temperature control systems may be used to vary the temperature of the propellant and therefore to modify its physical properties (mostly its electrical conductivity and viscosity). Such control variations may make it possible to work with the same thruster and propellant at variable propellant exhaust velocity (or equivalently variable specific impulse) to optimize the thruster performance during different phases of the spacecraft mission. Indeed, operation at variable specific impulse has been a goal of electric propulsion advocates. Such variable specific impulse thruster would be able to execute, in the same mission, fast maneuvers requiring high thrust and lower specific impulse (e.g., orbit insertion, spacecraft pointing, etc.), as well as maneuvers placing a premium on reduced propellant consumption (i.e., characterized by high specific impulse and lower thrust) (e.g., orbit maintenance, drag compensation, deorbit, etc.). Note, thrust and specific impulse may be inversely proportional when operating at constant power P, which is generally the case of spacecrafts employing electric propulsion.

In addition, advancements in design, fabrication, and operation of electrospray thruster heads described herein may include the use of a temperature control system to heat up thruster elements such as the emitter electrode 102, the extractor electrode 108, and/or the accelerator electrode, in order to evaporate at a higher rate films of liquid accumulated on the surfaces of these elements during thruster operation. Typically, the accumulation of these films may limit the lifetime of the thrusters because these films may be electrically conducting, and provide a path for current conduction between the electrodes, ultimately shorting the power supplies connected to the electrodes. The evaporation of these liquid films may eliminate this lifetime-limiting problem. Further, in many embodiments, a 70% efficiency in the conversion of electric power to jet kinetic power may be achieved providing an efficiency unrivaled by any other electric propulsion technology operating at power ranges available in SmallSats. Furthermore, the described embodiments and manufacturing processes may allow modification of the inner diameter of the emitter inner holes and hydraulic impedance channels, by varying the initial thickness of the emitter wafer 102 and etching parameters. This may be a key to implement either passive or pressurized propellant feeding.

Passive feeding of the propellant may be enabled by the present embodiments and manufacturing processes. Passive feeding is commonly used in thrusters in which the propellant flows through the surface of the emitter element or through the porous material sometimes used to make the emitter elements. Passive feeding typically is not utilized for thrusters in which the propellant flows through inner channels. However, if one could use passive feeding (i.e., driving the flow of propellant only by using the electric field implemented at an emitter tip), the propellant feed system may be greatly simplified because one will not need to use a large number of valves in the feed system.

Although specific electrospray thruster heads are discussed above with respect to FIGS. 1A-B, any of a variety of electrospray thruster heads including a variety of wafers, microchannels configurations, emitter array configurations, extractor configurations, accelerator configurations, and additional structures (e.g., separators, alignment rods, O-rings, etc.) as appropriate to the requirements of a specific application can be utilized in accordance with embodiments of the invention. Emitter electrode fabrication processes in accordance with embodiments of the invention are discussed further below.

### Emitter Electrode Fabrication Processes

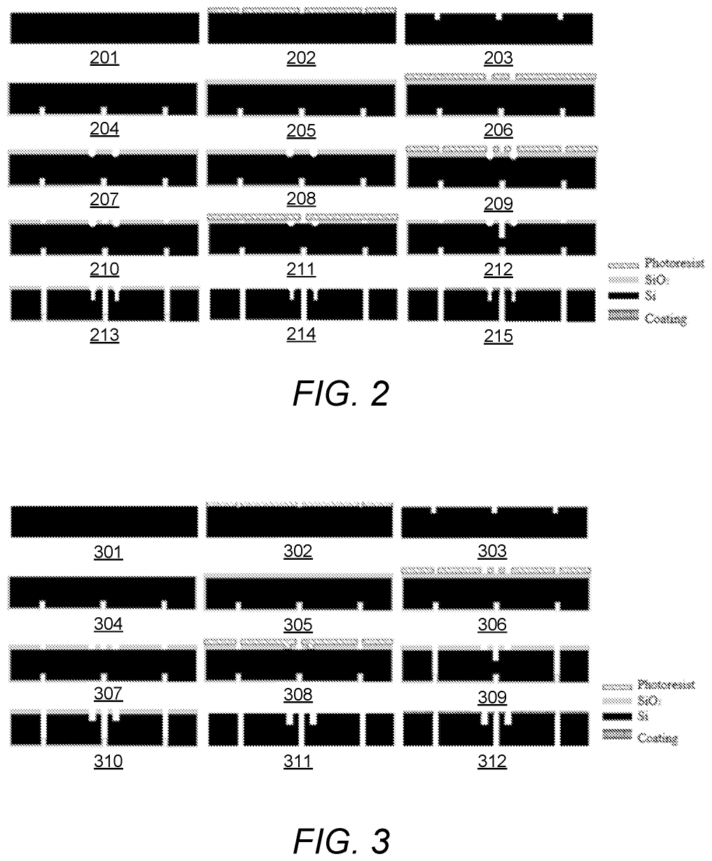

As described further above, an emitter array electrode may include emitters (may also be referred to as an “emitter array”) etched on a top side and microfluidic channels etched on a bottom side. A schematic diagram illustrating a microfabrication process for an emitter electrode in accordance with an embodiment of the invention is shown in FIG. 2. In many embodiments, the microfabrication processes of the emitter electrode may be done on wafers, such as, but not limited to, a double polished Si wafers. In various embodiments, the Si wafers may be from 25.4 mm up to 300 mm in diameter. As described herein, a key feature of the fabrication processes may include the work on both sides of the Si wafer. In several embodiments, one side may include the microchannels that may feed the propellant to the emitters on the opposite side of the SI wafer. For example, the emitters may include inner holes etched through the thickness of the Si wafer and connecting the microchannels from the other side, as further described below. In some embodiments, the microfabrication process described in FIG. 2 may allow for etching emitters with inner holes with diameters from 80 μm to 20 μm in Si wafers with thickness ranging from 525 μm to 200 μm. In some embodiments, the microfabrication processes described in FIG. 2 may obtain high yield emitters tips

In further reference to FIG. 2, the microfabrication process may include steps (201)-(203) that show the etching of the microfluidic channels on one side of the double polished Si wafer using a photolithography mask and deep reactive-ion etching (“DRIE”). For example, in step (201), the Si wafer may be cleaned using various methods known to one of skill in the art. In step (202), the backside may be patterned with channels (e.g., the microfluidic channels) that may be utilized for hydraulic impedance and/or as a common manifold. In some embodiments, the channels may be patterned using various photoresist systems. In step (203), the channels may be etched using timed DRIE, and the photoresist may be stripped. In step (204) the wafer may undergo a thermal oxidation to grow 1 μm of SiO₂ or 1 μm of SiO₂ may be deposited with Plasma Enhanced Chemical Vapor Deposition (“PECVD”) on the channels side. In step (205), the wafer may be flipped and a thick mask of SiO₂ may be deposited with PECVD on the opposite side of the etched microchannels. In steps (206)-(207), the wells and the emitter geometry without the inner hole may be etched on the SiO₂ mask with DRIE using a lithography mask backside aligned with the microchannels ends. In step (208), the silicon exposed, with the well and emitter geometries, may undergo isotropic etching to shape the tips of the emitters, using XF₂ dry etching or wet etching with hydrofluoric acid, nitric acid, and acetic acid (HNA). In steps (209)-(210), the inner hole of the emitters may be etched on the SiO₂ mask with DRIE using a lithography mask backside or front side aligned. In steps (211)-(212), the inner hole of the emitters may be 50 to 80% etched through the Si wafer using DRIE, depending on the initial wafer thickness using a lithography mask backside or front side aligned. In step (213), the wells and the etch through of the inner hole of the emitters connecting to the microchannels may be done by a DRIE step. In step (214), the SiO₂ may be removed using buffered oxide etch (“BOE”). In step (215) noble metal may be deposited on top of the emitters surface and inner hole using atomic layer deposition (ALD) or sputtering. In some embodiments, one or more of the above steps may be omitted or exchanged with another step. For example, steps (206), (207), and/or (208) may be changed and dry etching or wet etching omitted obtaining flat ending emitter tips with also good performance as shown in FIG. 3. In some embodiments, one or more additional steps may be added to the process without taking away from the key features of the emitter electrode.

A schematic diagram illustrating another microfabrication process for an emitter electrode in accordance with an embodiment of the invention is shown in FIG. 3. The microfabrication process may include steps (301)-(303) that show the etching of the microfluidic channels on one side of the double polished Si wafer using a photolithography mask and the DRIE. For example, in step (301), the Si wafer may be cleaned using various methods known to one of skill in the art. In step (302), the backside may be patterned with channels (e.g., the microfluidic channels) that may be utilized for hydraulic impedance and/or as a common manifold. In some embodiments, the channels may be patterned using various photoresist systems. In step (303), the channels may be etched using timed DRIE, and the photoresist may be stripped. In step (304), a photolithography mask may be used to cover the etched channels and leave circular opening at the ends of each channel. In step (305), the inner hole of the emitters may be etched 50-80% of the thickness of the wafer. In steps (306)-(307), the Si wafer may be flipped and a thick mask of SiO₂ may be deposited with PECVD on the opposite side of the etched microchannels. In steps (308)-(309), the wells and the emitter geometry with the inner hole may be etched on the SiO₂ mask with DRIE using a lithography mask backside aligned with the etched holes. In step (10), the wells and the etch through of the inner hole of the emitters connecting to the microchannels may be performed by a DRIE step. In step (311), the PECVD SiO₂ may be removed with BOE. In step (312) a noble metal may be deposited on top of the emitters surface and inner hole using atomic layer deposition (ALD) or sputtering. In various embodiments, the microfabrication process in FIG. 3 may be used to achieve lower inner hole diameters on the emitter. In some embodiments, one or more of the above steps may be omitted. In some embodiments, one or more additional steps may be added to the process without taking away from the key features of the emitter electrode.

Although specific microfabrication processes for emitter electrodes are discussed above with respect to FIGS. 2-3, any of a variety of processes and variations of processes for the fabrication of emitter electrodes as appropriate to the requirements of a specific application can be utilized in accordance with embodiments of the invention. For example, in some embodiments, various steps may be added, removed, and/or exchanged. Further, the various steps may be performed using processes, chemicals, percentages, concentrations, and/or techniques similar or equivalent to those described herein. In addition, in some embodiments, the various steps may be performed in differing order than those described above without taking away from the key features of the emitter electrode.

### High Hydraulic Impedance Microchannels

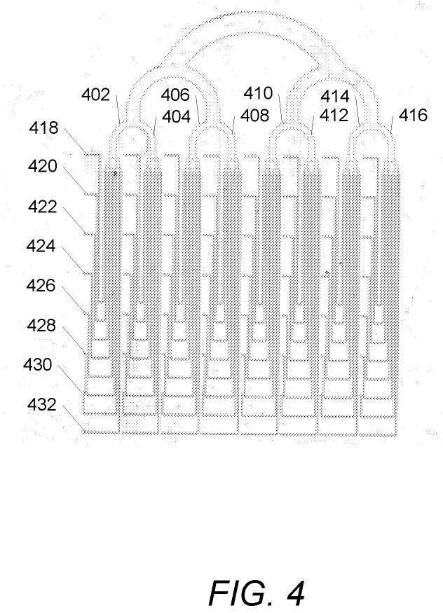

As described above, microfabrication processes may include etching in one side of a double-sided Si wafer the microfluidic channels where the liquid may be fed and branched to the emitters. Typically, since the hydraulic resistance that may be implemented in the circular conduit of each emitter is insufficient to divide the flow rate of propellant evenly among them, a larger flow restriction may be imposed using the microfluidic channels etched on the backside of the silicon wafer. In many embodiments, the propellant may be fed with a fused silica line or other component to a circular pool or main channel from which the flow may be bifurcated N times. Each bifurcation may create a pair of identical channels with half of the cross section of the parent channel. Each one of the 2^{N} final channels may discharge into the axial conduct of the emitter, and their width and length may make them the major flow restrictors. Because the width and depth of these 2^{N} channels can be etched with small tolerances, and since they are the main contributors to the hydraulic resistance, the network of channels may distribute the propellant evenly among the emitters. An optical image of fabricated microchannels in accordance with an embodiment of the invention is shown in FIG. 4. The microfluidic etched pattern 400 may include 64 channels that are 20×20 μm in width and depth and 7500 μm in length. Each branch 402, 404, 406, 408, 410, 412, 414, 416, may feed an emitter, in this case, an 8×8 emitter array. For example, the first branch 402 may include a first channel 418, a second channel 420, a third channel 422, a fourth channel 424, a fifth channel 426, a sixth channel 428, a seventh channel 430, and an eighth channel 432. Each of the other branches 404, 406, 408, 410, 412, 414, 416 may include eight channels.

In reference to FIG. 4, the geometry of the microchannels may be tailored to obtain the required hydraulic resistance that provides the proper flow rate when a specific range of pressure difference is applied. The volumetric flow rate of propellant is given by:

$$Q = \frac{P}{μ {R}_{H}}$$

where μ is the viscosity of the propellant. The hydraulic resistance R_{H} is the sum of the hydraulic resistances of the fused silica line, the array of conduits in the tubular emitters, and of the network of microchannels:

$${R}_{H} = \frac{8 {L}_{f}}{π {R}_{f}^{4}} + \frac{1}{{2}^{N}} \frac{8 {L}_{c}}{π {R}_{c}^{4}} + {\sum }_{i = 1}^{N} \frac{1}{{2}^{i}} \frac{12 {l}_{i}}{{h}_{i} {w}_{i}^{3}} {[ 1 - \frac{192 {w}_{i}}{{h}_{i} {π}^{5}} {\sum }_{k} {( 2 k + 1 )}^{- 5} tanh ( \frac{( 2 k + 1 π {h}_{i} )}{2 {w}_{i}} ) ]}^{- 1}$$

where L_{f} and R_{f}, and L_{c} and R_{c} are the length and radius of the fused silica line and the emitters' conduits, respectively, and Lᵢ, hᵢ and wᵢ are the length, depth and width of a microfluidic channel in the i^{th} bifurcation, respectively.

In many embodiments, the first step before etching the channels may be to treat the Si wafer with an RCA cleaning to ensure a clean surface and maximize the photoresist's adhesion. The RCA procedure is typically an RCA-2 clean to remove metals from the surface, followed by an RCA-1 clean to remove organic contaminants. Typically, RCA-1 clean should be sufficient in processes that do not include metal deposition or lift-off. In several embodiments, the RCA-1 clean may be performed with a 6:1:1 volume solution of Deionized (“DI”) water, NH₄OH (27%), and H₂O₂ (30%) heated at 70 C. Once finished, the Si wafer may be rinsed several times with DI water and undergo a dehydration process to remove water physisorbed by the Si wafer's surface. This process may be repeated after each lithography and etching during the fabrication processes.

In various embodiments, to micromachine the channels, a pattern may be transferred on one side of the cleaned polished Si wafer using a photoresist and photolithography. In some embodiments, the microfluidic system may be etched using deep reactive ion etching (“DRIE”) with a modified standard Bosch recipe known to one of skill in the art. In several embodiments, the number of microfluidic channels may be readily increased to fed larger emitter arrays, while keeping the same length and the same distance between each microchannel end.

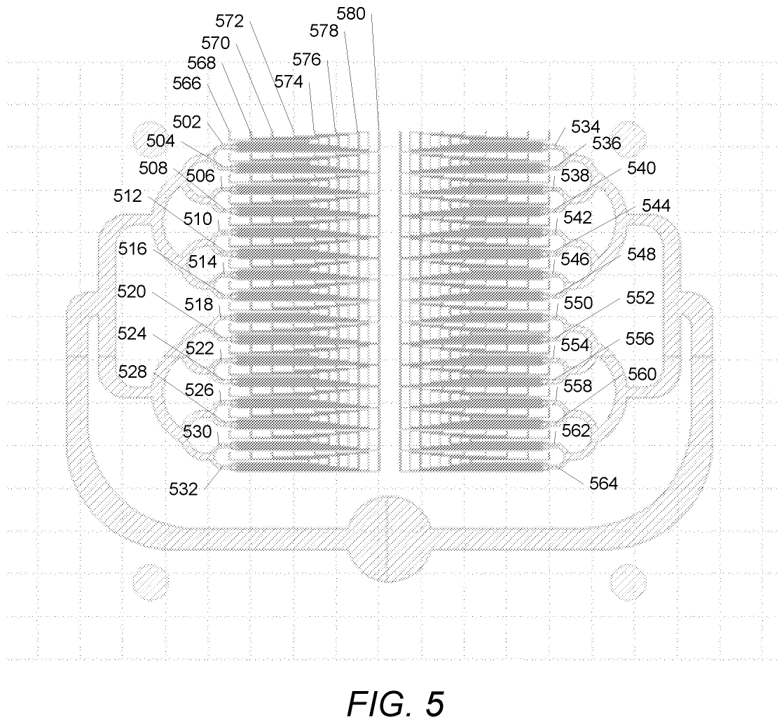

A schematic diagram illustrating a microchannel for a 16×16 emitter array electrode in accordance with an embodiment of the invention is shown in FIG. 5. The microfluidic channel configuration 500 may include 256 channels to feed a 16×16 emitter array electrode. For example, each branch 502, 504, 506, 508, 510, 512, 514, 516, 518, 520, 522, 524, 526, 528, 530, 532, 534, 536, 538, 540, 542, 544, 546, 548, 550, 552, 554, 556, 558, 560, 562, 564 may feed an emitter, in this case, a 16×16 emitter array. For example, the first branch 502 may include a first channel 566, a second channel 568, a third channel 570, a fourth channel 572, a fifth channel 574, a sixth channel 576, a seventh channel 578, and an eighth channel 580. Each of the other branches 504, 506, 508, 510, 512, 514, 516, 518, 520, 522, 524, 526, 528, 530, 532, 534, 536, 538, 540, 542, 544, 546, 548, 550, 552, 554, 556, 558, 560, 562, 564 may include eight channels.

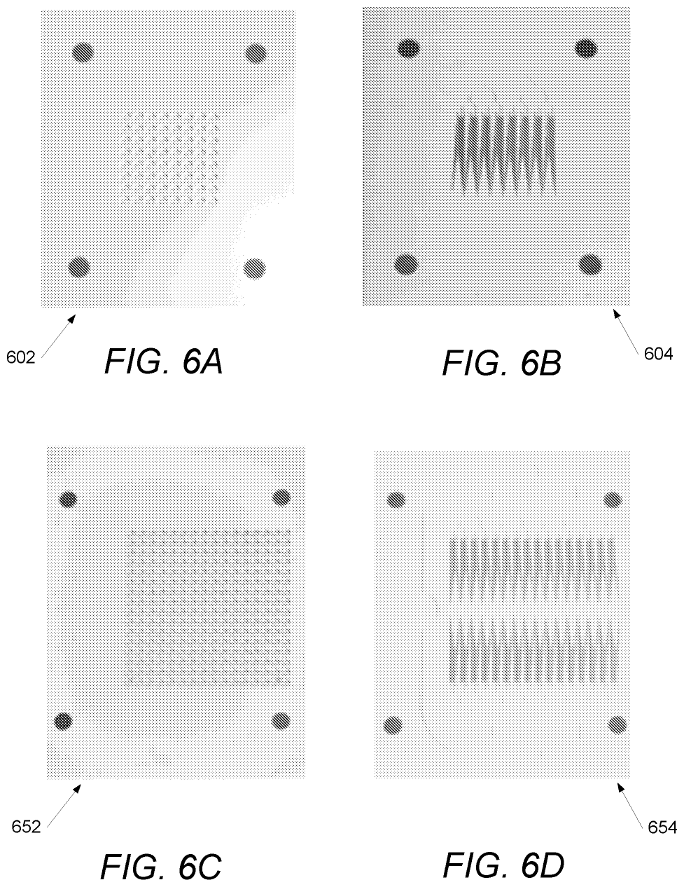

A microchannel array may be etched in various electrode configurations such as, but not limited to, a 64-emitter electrode and a 256-emitter electrode. A 64-emitter electrode having a front side with 64 emitters and a backside with flow resistive channels in accordance with an embodiment of the invention is shown in FIGS. 6A-B, respectively. FIG. 6A illustrates the front side 602 of the emitter electrode having 64 emitters. FIG. 6B illustrates the backside 604 of the emitter electrode having 64 flow resistive channels corresponding to the 64 emitters on the front side 602 of the emitter electrode. FIGS. 6C-D illustrate a 256-emitter electrode having a front side with 64 emitters and a backside with flow resistive channels in accordance with an embodiment of the invention. FIG. 6C illustrates the front side 652 of the emitter electrode having 256 emitters. FIG. 6D illustrates the backside 654 of the emitter electrode having 256 flow resistive channels corresponding to the 256 emitters on the front side 652 of the emitter electrode. In many embodiments, to smooth the microfluidic channels' surface and to create a stopping layer for the emitter center hole etching, the etched Si wafer may undergo a thermal oxidation process. As described above, the microfabrication processes may include the growth of a 1 μm SiO₂ layer which may be done by a wet or dry oxidation process.

### Emitter Array and Surrounding Well Fabrication Processes

As described above, the fabrication processes may include the fabrication of the emitters on the top part of the Si wafer. In many embodiments, the process to etch the emitters may be performed using various processes including, but not limited to, a three-step etching process where the center hole of the emitter may be etched through the entire thickness of the Si wafer and thereby connecting the emitters to the end of each microchannel. In some embodiments, a thick Silicon oxide mask deposited with PECVD on top of the thermal oxidation layer may be utilized to perform this step. In various embodiments, the use of a SiO₂ mask may allow for a higher etching quality with fewer defects (rather than using a very thick photoresist). In some embodiments, an HDMS adhesion promotion treatment may be used, and the emitter pattern may be transferred to a photoresist layer backside aligned with the microchannels ends.

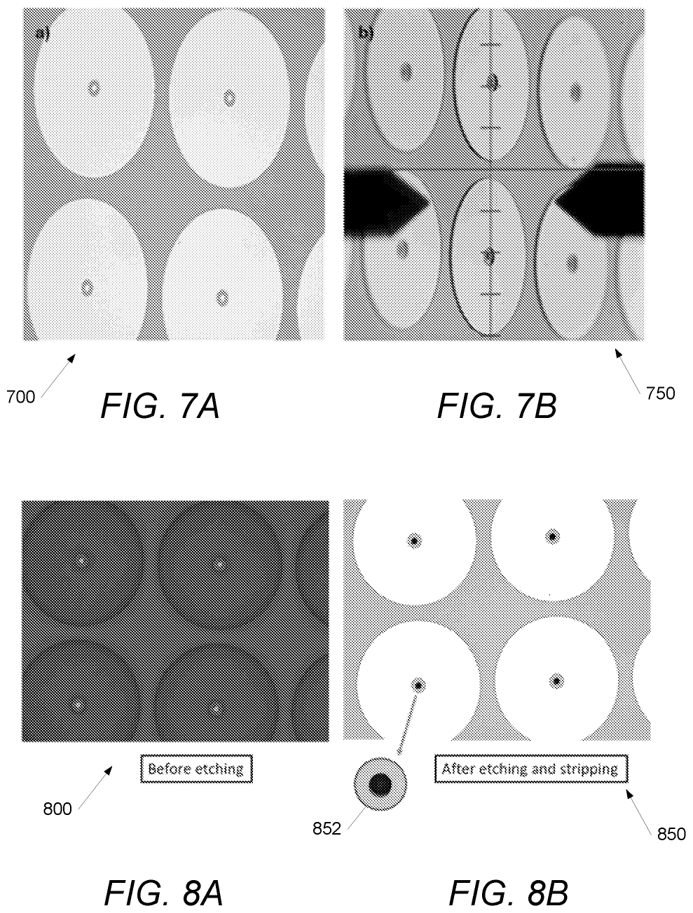

In several embodiments, the emitter pattern may include a surrounding well to avoid flooding of the thruster as well as providing for cross-talking between the emitters. As described above, a SiO₂ mask may be obtained by etching the emitter pattern with a SiO₂ deep reactive etching recipe. Fabrication of emitters and surrounding well pattern in accordance with an embodiment of the invention is shown in FIGS. 7A-B. In FIG. 7A, a profile view 700 includes photoresist layer on top of the SiO₂ with the emitter and surrounding well pattern is illustrated. In FIG. 7B, a profile view 750 after the etching of the SiO₂ is provided. In various embodiments, following the SiO₂ etch, the photoresist may be stripped, and a new photoresist layer may be spin-coated to pattern the center holes of the emitters. In some embodiments, the center holes may be etched almost all the wafer thickness using a reactive ion etching (“RIE”), such as, but not limited to, DRIE, with a modified Bosh recipe. In some embodiments, the photoresist may then be stripped and the wafer may be cleaned by a RCA-1 process.

Center hole lithography before and after the etching and stripping process is shown in FIGS. 8A-B. In FIG. 8A, fabrication of emitters and surrounding well pattern before 800 etching in accordance with an embodiment of the invention is illustrated. In FIG. 8B, fabrication of emitters and surrounding well pattern after 850 etching and stripping in accordance with an embodiment of the invention is illustrated. In many embodiments, the SiO₂ mask with the geometry of the emitter and the surrounding well may undergo a last RIE process that finishes the center hole 852 etch through and defines the emitter height and the surrounding well depth. Once finished with the final RIE process, the emitter electrode may be soaked in a buffered oxide etch bath (e.g., BOE 6:1) to remove the SiO₂ layer.

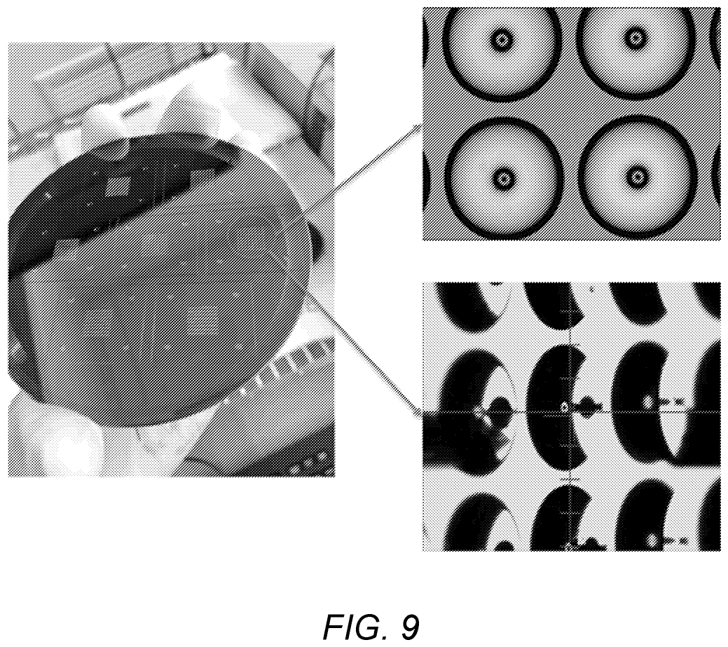

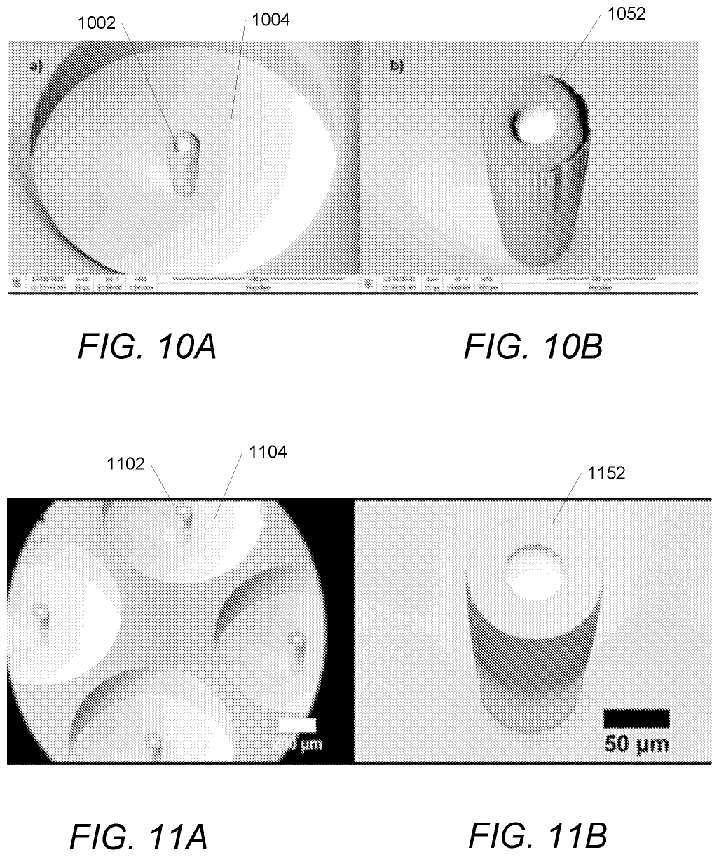

FIGS. 9-15 illustrate some results of the fabrication processes of the emitter electrode. Results of etching of emitters in accordance with an embodiment of the invention is shown in FIG. 9. In FIG. 9, overall images of the results of the etching of the emitters are illustrated. Scanning electron microscope (“SEM”) images illustrating an etched emitter and pool in accordance with an embodiment of the invention is shown in FIGS. 10A-B. In FIG. 10A, the SEM images of a 300 μm etched emitter 1002 and pool 1004 are illustrated. In FIG. 10B, a close-up of an etched emitter 1052 is illustrated. In many embodiments, the emitter may have a 30 μm wall thickness. SEM images illustrating another etched emitter and pool in accordance with an embodiment of the invention is shown in FIGS. 11A-B. In FIG. 11A, a plurality of etched emitter and pool (e.g., first etched emitter 1102 and first pool 1104) are illustrated. In FIG. 11B, a close-up an etched emitter 1152 is illustrated.

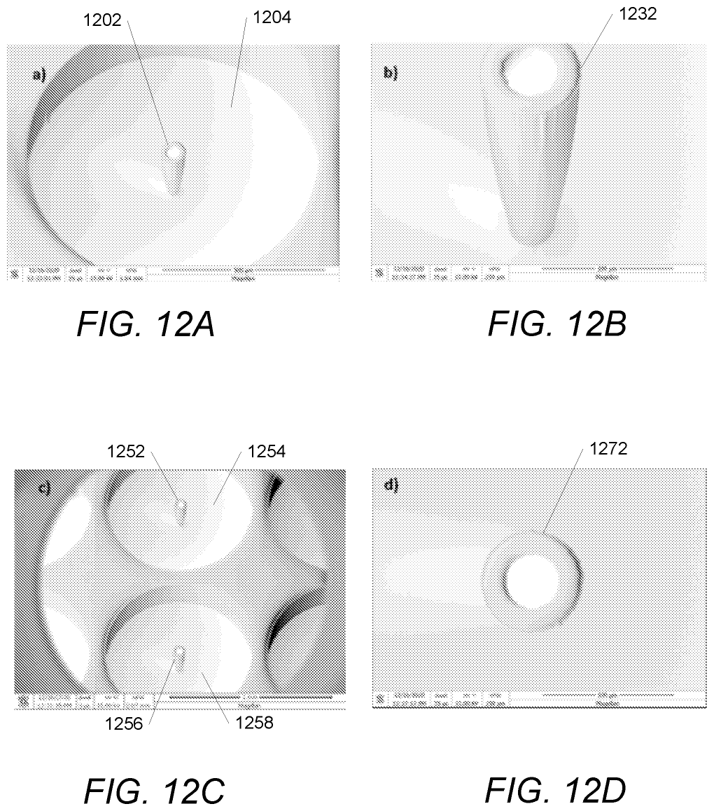

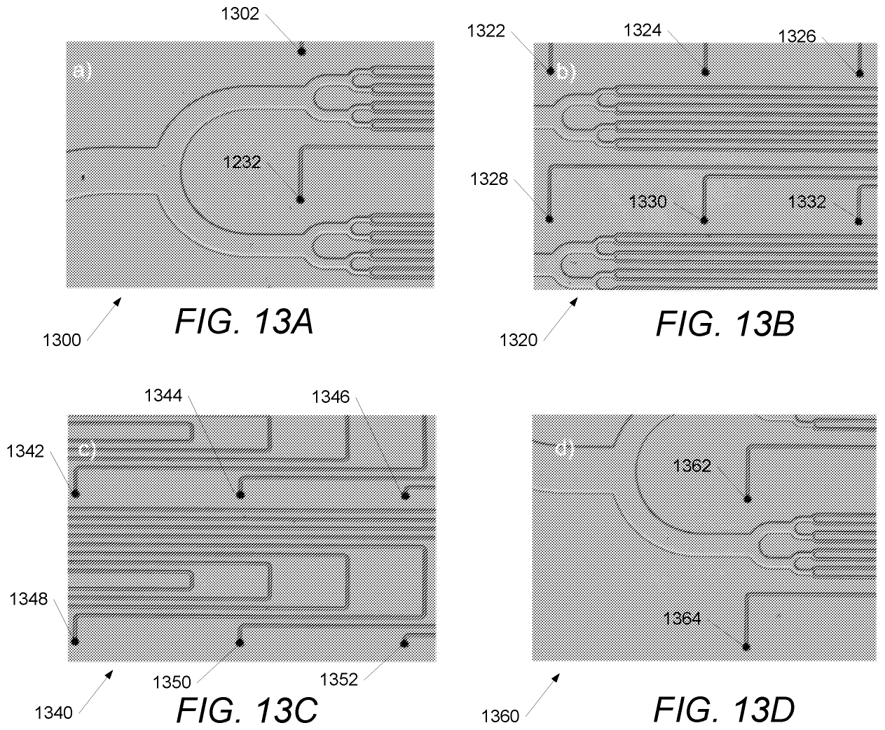

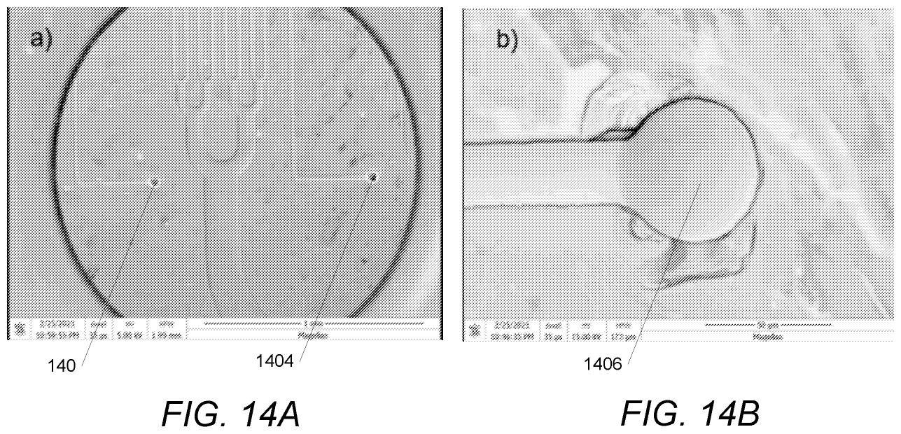

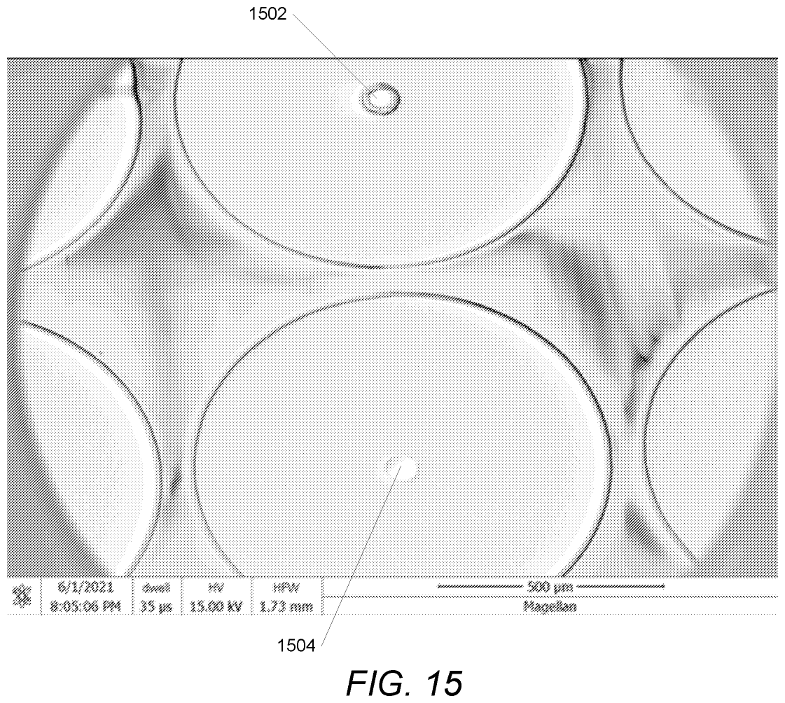

SEM images illustrating another etched emitter and pool in accordance with an embodiment of the invention is shown in FIGS. 12A-D. In FIGS. 12A-D, the SEM images of 300 μm etched emitters 1202, 1232, 1252, 1256 and pools 1204, 1254, 1258 are illustrated. In various embodiments, the emitters 1202, 1232, 1252, 1256 may have a 20 μm wall thickness. Optical images illustrating emitter center holes matching ends of microchannels in accordance with an embodiment of the invention are shown in FIGS. 13A-D. The optical pictures 1300, 1320, 1340, 1360 illustrate the center hole of the emitters etch matching the end of each microchannel etch on the opposite side of the wafer. For example, in FIG. 13A, optical picture 1300 shows center holes of the emitters etch matching 1302, 1304 end of microchannel etches. In FIG. 13B, optical picture 1320 shows center holes of the emitters etch matching 1322, 1324, 1326, 1328, 1330, 1332 end of microchannel etches. In FIG. 13C, optical picture 1340 shows center holes of the emitters etch matching 1342, 1344, 1346, 1348, 1350, 1352 end of microchannel etches. In FIG. 13D, optical picture 1360 shows center holes of the emitters etch matching 1362, 1364 end of microchannel etches. SEM images illustrating another emitter center holes matching an end of microchannels in accordance with an embodiment of the invention is shown in FIGS. 14A-B. In FIGS. 14A-B, the SEM images of the etch through of the emitter center holes matching 1402, 1404, 1406 the end of the microchannels still with the thermal SiO₂. In several embodiments, the SiO₂ thermal oxidation layer acts as a stopping layer for the etching. High yield emitter tips 1502, 1504 in accordance with an embodiment of the invention is shown in FIG. 15. The chamfer may be etched under the SiO₂ mask for high yield emitter tips.

Although specific emitter electrodes and fabrication of emitters and well patterns are discussed above with respect to FIGS. 4-15, any of a variety of emitter electrodes and well patterns as appropriate to the requirements of a specific application can be utilized in accordance with embodiments of the invention. For example, the emitters may include any number of emitters and microchannels, microfluidic configurations, various well patterns, etc. Extractor electrode fabrication processes in accordance with embodiments of the invention is discussed further below.

### Extractor Electrode Fabrication Processes

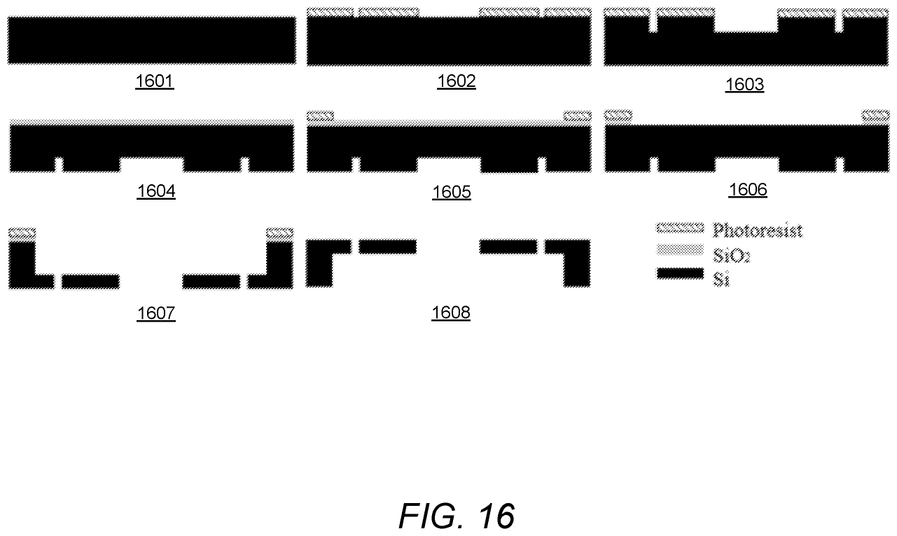

As described above, an electrospray thruster typically includes an emitter electrode and an extractor electrode. The extractor may be a wafer with an array of holes etched through where each extractor hole may be concentric to each emitter. A schematic diagram illustrating a microfabrication process for an extractor electrode in accordance with an embodiment of the invention is shown in FIG. 16. In many embodiments, for the extractor electrode fabrication, a double side Si polished wafer, with a greater thickness than the Si wafer may be used. To micromachine the circular holes, matching the number of emitters in the emitter electrode and centered with the center holes of the emitters, a designed pattern may be transferred on to one side of the cleaned polished Si wafer using a photoresist and photolithography. For example, the microfabrication process may include etching the pattern using RIE, with a modified standard Bosh recipe. For example, in step (1601), the Si wafer may be cleaned using various methods known to one of skill in the art. In step (1602), the backside may be patterned with channels (e.g., the microfluidic channels) that may be utilized for hydraulic impedance and/or as a common manifold. In some embodiments, the channels may be patterned using various photoresist systems. In step (1603), the channels may be etched using timed RIE, and the photoresist may be stripped. In step (1604), the wafer may then be flipped and a layer of SiO₂ may be deposited using PECVD. In step (1605), the entire area of the extractor, besides a frame that may be used later for the final bonding, may be etched with RIE. In step (1606), the SiO₂ layer may be first etched with an SiO₂ etch recipe and then, in steps (1607-1608), the Si may be etched with a modified Bosh process. The length of this final etch may dictate the distance between the extractor and the emitters electrode as follows: Gap between the emitter and extractor electrode=Depth of final etch in extractor electrode−thickness of emitter electrode.

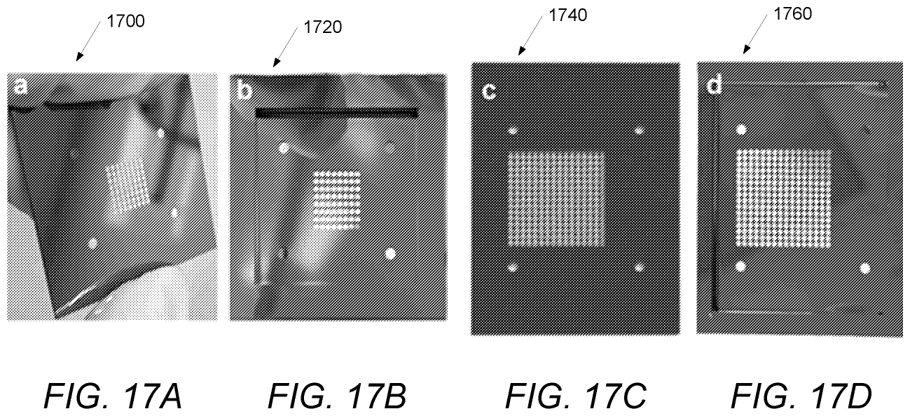

All the various parameters described that dictate the distance between the emitter electrode and extractor electrode may readily be controlled to minimize the voltage required and current intercepted during operation. The holes on the extractor described herein may match the diameter of the well of the emitter electrode but can easily be reduced to allow the addition of an accelerometer grid. Two extractor electrodes having a front with 64 holes and 256 holes and a back with an etch and frame for anodic bonding in accordance with an embodiment of the invention is shown in FIGS. 17A-D. A finished extractor electrode for a 64-emitter electrospray thruster assembly is depicted. In FIG. 17A, a front side 1700 of the extractor with 64 holes is illustrated. In FIG. 17B, a backside 1720 of the extractor with the final etch and the frame that may be used for the anodic bonding is illustrated. In FIG. 17C, a front side 1740 of the extractor with 256 holes is illustrated. In FIG. 17D, a backside 1760 of the extractor with the final etch and the frame that may be used for the anodic bonding is illustrated.

Although specific microfabrication processes for extractor electrodes and embodiments of extractor electrodes are discussed above with respect to FIGS. 16-17D, any of a variety of processes and variations of processes for the fabrication of extractor electrodes as appropriate to the requirements of a specific application can be utilized in accordance with embodiments of the invention. For example, in some embodiments, various steps may be added, removed, and/or exchanged. Further, the various steps may be performed using processes, chemicals, percentages, concentrations, and/or techniques similar or equivalent to those described herein. In addition, in some embodiments, the various steps may be performed in differing order than those described above without taking away from the key features of the extractor electrode. In Moreover, a variety of extractor electrodes as appropriate to the requirements of a specific application can be utilized in accordance with embodiments of the invention. For example, the extractors may include any number of holes, hole patterns, etc. Accelerator fabrication processes in accordance with embodiments of the invention is discussed further below.

### Accelerator Fabrication Processes

In various embodiments, a third electrode may be used to further accelerate emitted droplets and ions and increase the thrust and the specific impulse of electrospray thrusters. In many embodiments, the accelerator may be integrated in the system and isolated electrically from the extractor electrode through a glass layer. Alignment and bonding of various components of electrospray thrusters in accordance with embodiments of the invention is discussed further below.

### Alignment and Bonding

As described above, an electrospray thruster source (e.g., an electrospray thruster head) may include an emitter electrode having emitters etched on a top side and microfluidic channels etched on a bottom side, an extractor electrode, and a platform (e.g., a borosilicate wafer) to align, bond, and/or feed a propellant and seal the pool of propellant. Further, in some embodiments, the electrospray thruster source may also include an accelerator grid.

In many embodiments, the various components may be bonded into a single compact thruster head. In some embodiments, the backside of the emitter electrode may be anodically bonded to a platform wafer (e.g., a borosilicate wafer) thereby sealing the flow-resistive microchannels. In a variety of embodiments, the borosilicate wafer may have a small orifice and one or more alignment holes (e.g., four alignment holes). In some embodiments, the alignment holes may be micromachined with the use of a high-resolution femtosecond laser. In some embodiments, the small orifice may be used for the insertion and bonding of a fused silica tube that may feed the propellant from an external reservoir to the flow-resistive channels of the emitter electrode. In many embodiments, during the RIE process of the microfabrication of each component (e.g., the emitter electrode and the extractor electrode) precise alignment holes (e.g., four alignment holes) may be etched through, matching those in the borosilicate wafer. These etched alignment holes may help to bond and align with high precision all of the components without the need for high precision tools.

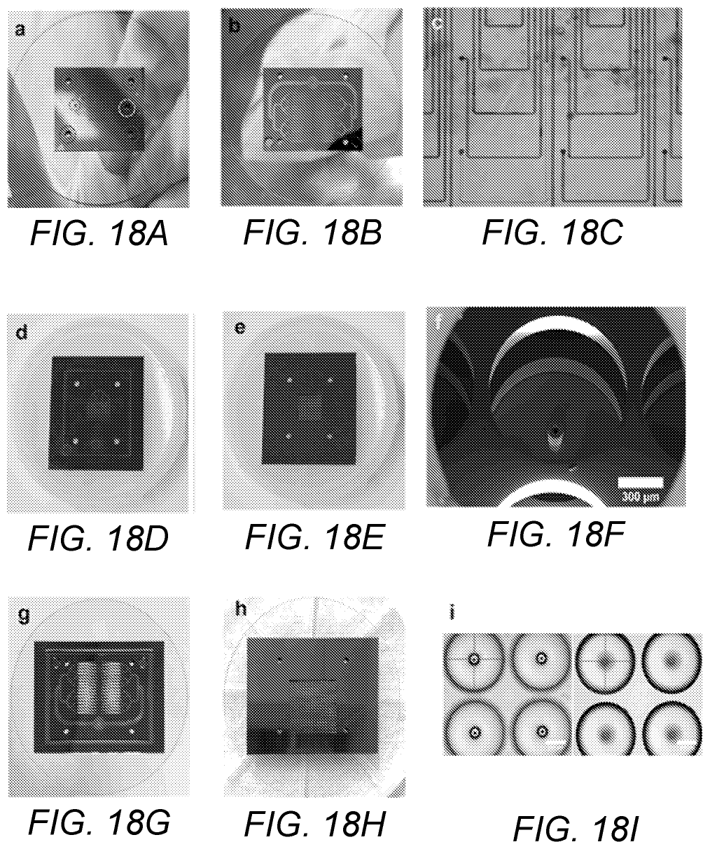

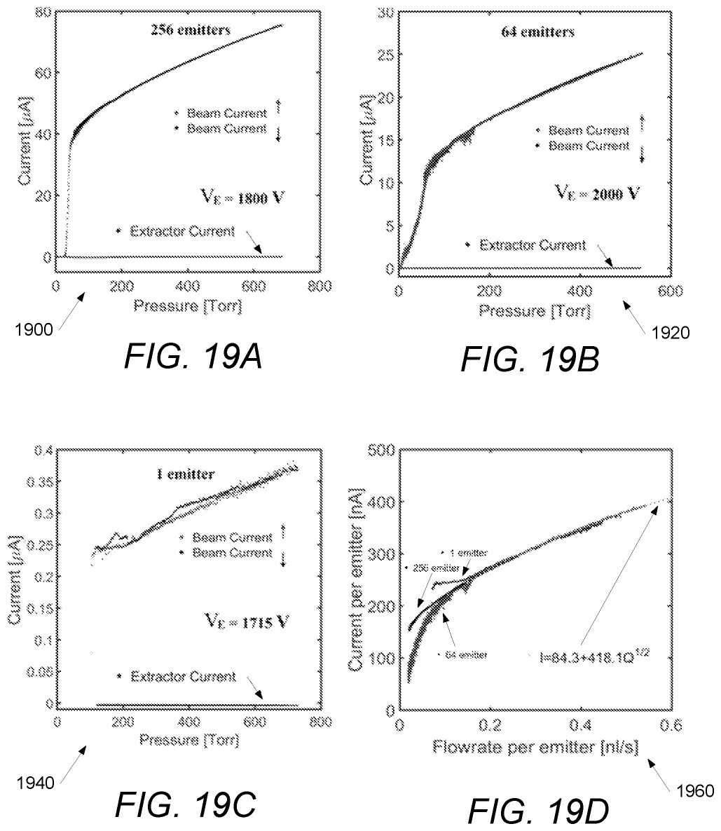

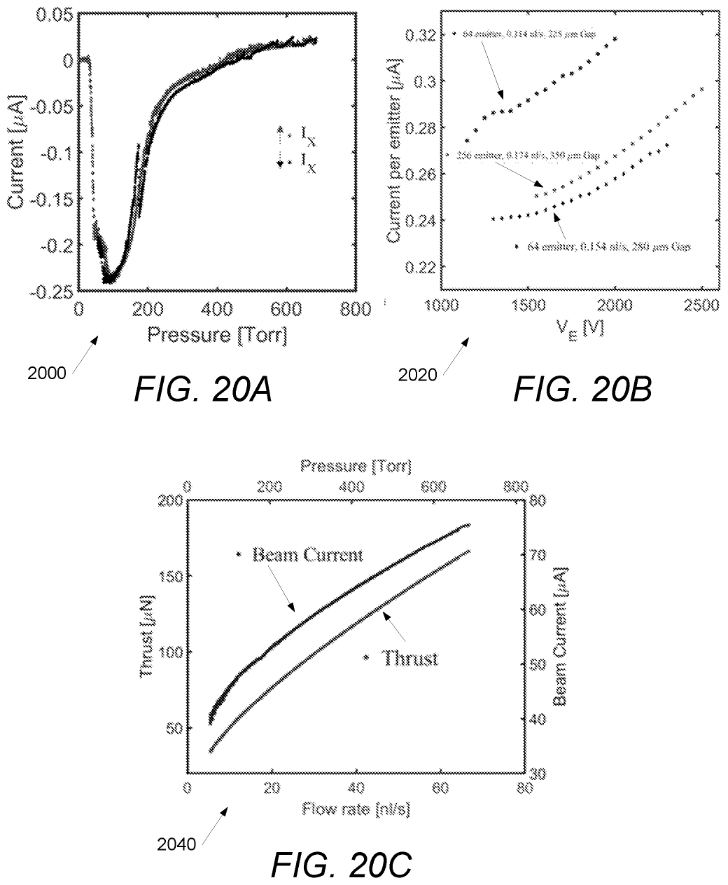

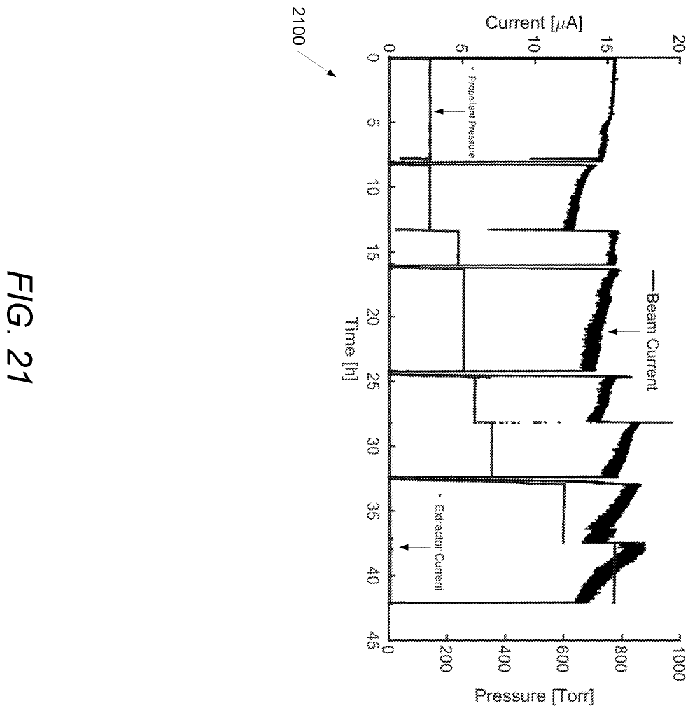

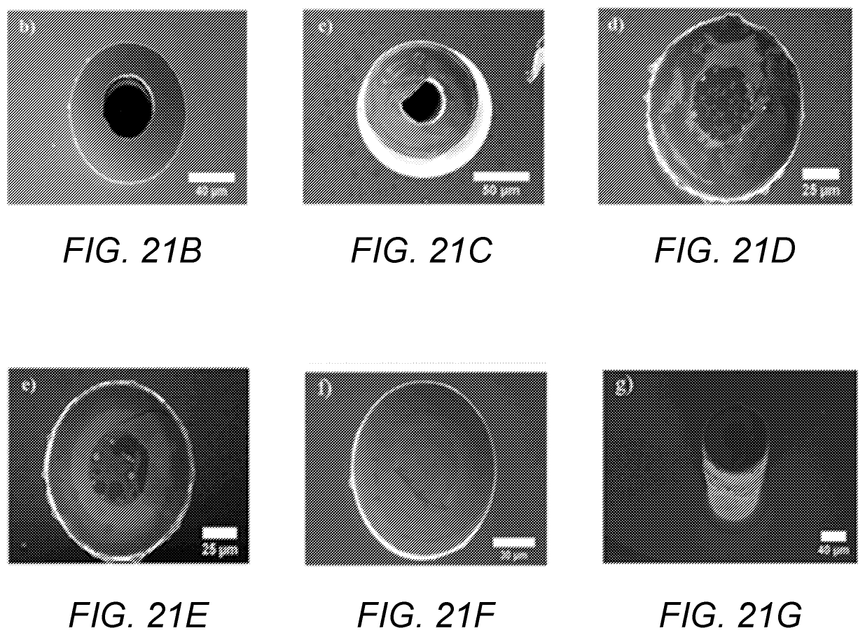

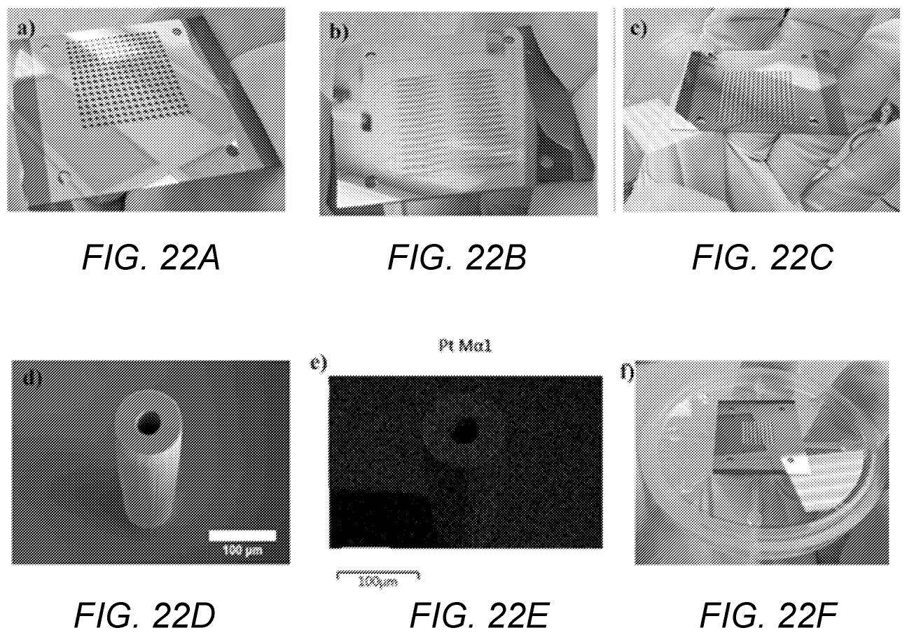

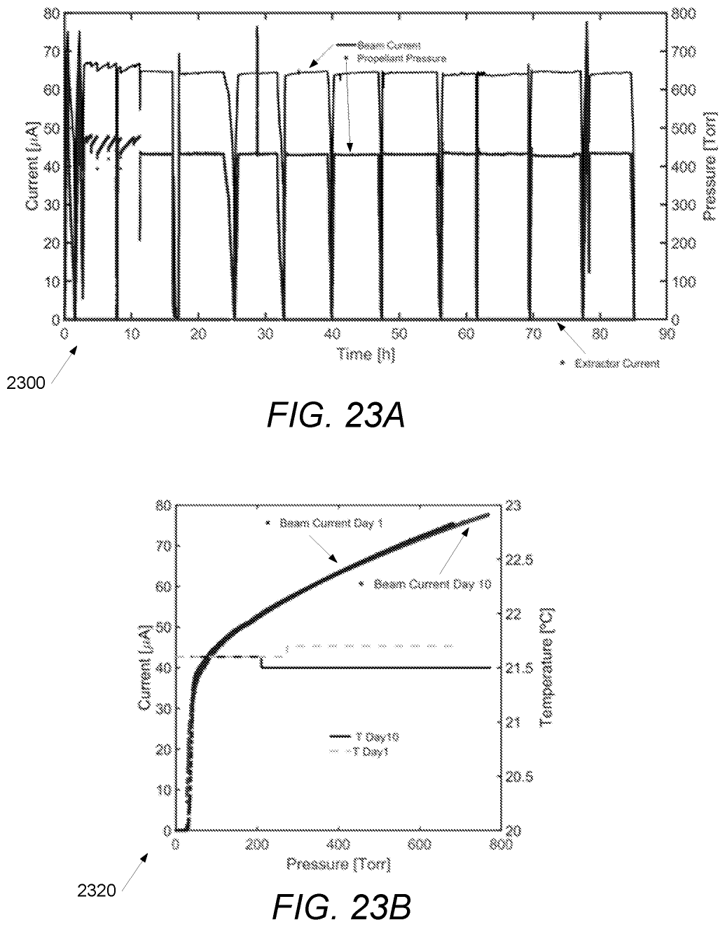

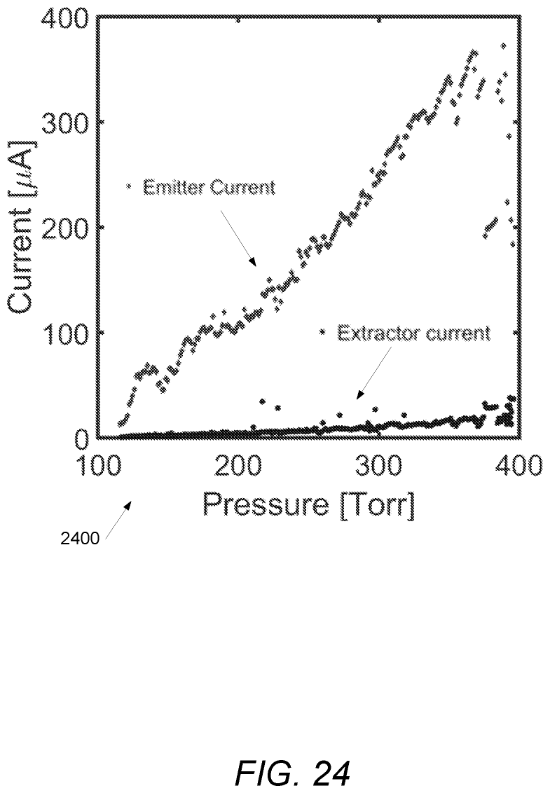

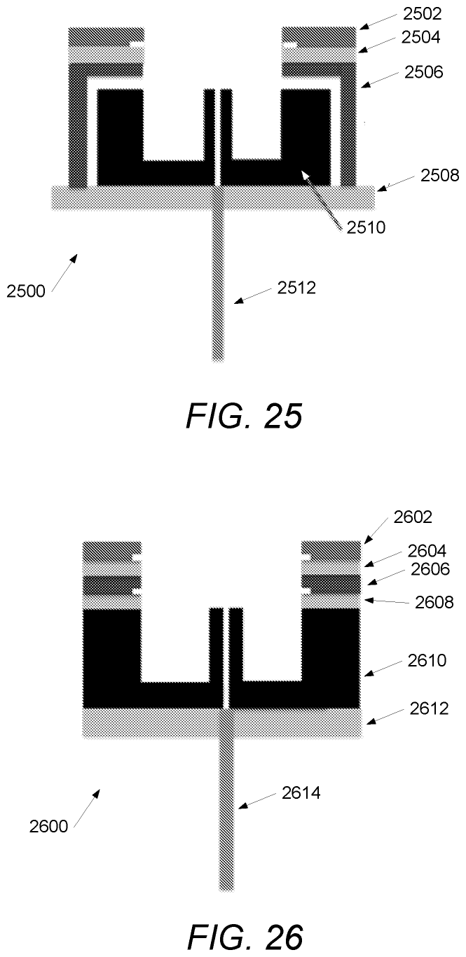

A borosilicate wafer anodically bonded to a 64-emitter electrode and 256-emitter electrode sealing flow-resistive microchannels in accordance with an embodiment of the invention is shown in FIG. 18A-B, respectively. In FIGS. 18C, a test displaying absence of propellant leakage in the sealed network of microfluidic channels in accordance with an embodiment of the invention is shown.

A bottom view and a top view of a 64 holes extractor electrode bonded on a glass wafer is shown in FIGS. 18D-E. In various embodiments, the 64 holes extractor electrode bonded on the glass wafer may result in a completed 64-emitter electrospray source. In many embodiments, an extractor frame may be bonded into the glass wafer leaving a gap with the emitter electrode. A SEM image of the emitter/extractor region for one emitter in accordance with an embodiment of the invention is shown in FIG. 18E. In some embodiments, the distance between the emitters and the extractor holes may be defined during the fabrication process, as further described above. A bottom view and top view of a 256 holes extractor electrode bonded on a glass wafer is shown in FIGS. 18G-H. In several embodiments, the 256 holes extractor electrode bonded on the glass wafer may result in a completed 256-emitter electrospray source. A top view of the electrospray thruster head with the three components bonded and aligned is depicted in FIG. 18I. In many embodiments, all three components may be aligned with a deviation below 5 μm by using the etched alignment holes during the anodic bonding method as described herein.

In many embodiments The borosilicate glass wafer may include through holes to connect the emitter, extractor and accelerator electrode to the desired electric potentials. In some embodiments, a third electrode (e.g., an accelerator electrode), can be integrated in the system by anodically bonding a glass layer on top of the extractor and the third electrode on top of it. The glass layer may provide electrical insulation and a surface where to bond the electrodes. In some embodiments, the third electrode may be aligned with the rest of the components using the same alignment holes.

Although alignment and bonding of components of an electrospray thruster source are discussed above with respect to FIGS. 18A-I, any of a variety of alignment and bonding processes as appropriate to the requirements of a specific application can be utilized in accordance with embodiments of the invention. Results and considerations in accordance with embodiments of the invention are discussed further below.

### Results and Considerations

Electrospray thrusters are able to provide extremely low and precise thrust, whereas other electric propulsion systems typically cannot be downscaled to work efficiently at low power levels (e.g., 1-100 W). For applications in which precision and low level of thrust is the goal, electrospray thrusters may be the most suitable option. However, the same technology can easily be scaled up to larger spacecrafts that can provide larger power levels (e.g., larger than 100 W). The microfabrication processes described above may be used to adjust the total number of emitters so that the available power can be used for propulsion, without downgrading the efficiency of the propulsion system. The ability to modify the number of emitters by orders of magnitude makes the propulsion system scalable to different size-classes of spacecrafts. Furthermore, the propellant used is inert and harmless to the spacecraft, as opposed to other electric propulsion technologies like FEEP that use liquid metals as a propellant. Electrospray ionization is a soft ionization technique (unlike plasma discharge techniques used by most other electric propulsion technologies) and thus eliminating emissions of high-power RF, IR, visible, or UV radiation. In addition, the propellant utilized is a liquid at operating temperatures, so there is no energy wasted for melting it, nor thermal issues related to the need to heat up the propellant (like for FEEPs) or to eliminate thermal loads produced by a plasma discharge chamber.

A thruster relying on electrospray technology may not require high-pressure valves, tanks with risks of explosion or high temperature components. Thus, it may be a safe and efficient propulsion system. Electrospray thrusters operate by accelerating charged droplets of varying charge to mass rations, pure ions, or a mixture of them. These different modes of operation enable the possibility of operating at different specific impulses. Moreover, the present embodiments provide control over the specific impulse when operating on a specific mode (by changing the acceleration voltage and/or changing the flow rate of propellant and/or changing its temperature. Operation of a variable specific impulse may be a highly desirable capability for the optimization of different maneuvers required by a mission.

Multiemitter electrospray sources described herein may be manufactured using materials and tools from the semiconductor industry. The cost associated with the manufacturing processes may be lower than other electric propulsion technologies. For example, materials may be cheaper and the manufacturing processes may be easily scaled up in an industrial environment. Exemplary multiemitter electrospray sources have been tested in vacuum chambers. Graphs illustrating results of a 1 single emitter electrode, a 64-emitter electrode, and a 256-emitter electrode in accordance with an embodiment of the invention are shown in FIGS. 19A-D. In FIG. 19A, graph 1900 includes results of the 256-emitter electrode. In FIG. 19B, graph 1920 includes results of the 64-emitter electrode. In FIG. 19C, graph 1940 includes results of the single emitter electrode. In FIGS. 19A-C, emitter current as a function of pressure drop driving the propellant flow are shown. In many embodiments, the pressure drop driving the propellant and the emitter potential may be fixed. The current and flow rate per emitter for the three sources (i.e., single, 64-, and 256-emitter electrodes) in accordance with an embodiment of the invention is shown in FIG. 19D. In FIG. 19D, graph 1960 illustrates current and flow rate per emitter for the three sources.

A graph 2000 showing extractor current as a function of pressure driving the propellant flow in accordance with an embodiment of the invention is shown in FIG. 20A. A graph 2020 showing variation of the current per emitter with emitter voltage, for three different electrospray sources, in accordance with an embodiment of the invention is shown in FIG. 20B. A graph 2040 showing emitter current as a function of the emitter potential is shown in accordance with an embodiment of the invention in FIG. 20C.

A graph 2100 illustrating a 64-emitter source without coating 42 hours performance test using EMI-IM propellant with current as a function of pressure in accordance with an embodiment of the invention is shown in FIG. 21A. In various embodiments, the pressure has to be increased to keep the current constant.

An evolution of the electrochemical film deposition that clogs the emitters in accordance with an embodiment of the invention is shown in FIGS. 21B-G. In FIGS. 21B-G, the clogging of the non-coated silicon emitters due the electrochemical deposition generated by the counter ion on the surface of the silicon is illustrated.

A 256-emitter electrode source with a 100 nm platinum coating on the front side without contamination on the backside (microchannels) in accordance with an embodiment of the invention is shown in FIG. 22A. The backside of the coated 256-emitter array without platinum on it in accordance with an embodiment of the invention is shown in FIG. 22B. The 256-emitter electrode source coated anodically bonded to the glass wafer in accordance with an embodiment of the invention is shown in FIG. 22C. A SEM picture of an emitter coated with platinum in accordance with an embodiment of the invention is shown in FIG. 22D. An EDX mapping of the emitter in accordance with an embodiment of the invention is shown in FIG. 22E. A 64-emitter array electrode coated with platinum anodically bonded to a glass wafer in accordance with an embodiment of the invention is shown in FIG. 22F.

FIG. 22A is a graph 2300 showing a 86 hour performance test using EMI-IM as propellant of a 256-emitter electrospray source with a 256-emitter array electrode with a Platinum coating as described in FIG. 22A-F. A graph 2320 showing two pressure current curves of the 256-emitter source performance test taken at the first day and last day of the test in accordance with an embodiment of the invention is shown in FIG. 23B. The graph 2320 shows pressure-current curves of the sources taken the first day of the test and the last day of the test demonstrating that the platinum coating avoids electrochemical degradation of the emitters or clogging.

In many embodiments, electrospray sources may work with different propellants such as, but not limited to, ionic liquids. A graph 2400 showing emitter and extractor current as a function of pressure using EMI-DCA as propellant for a 64-emitter electrospray source in accordance with an embodiment of the invention is shown in FIG. 24. Graph 2400 shows a current-pressure curve obtained with a 64-emitter electrospray source operating with the ionic liquid EMI-DCA. In several embodiments, this can be used to tailor the operation in a given thruster, for example by having two different tanks with propellants A and B. In such embodiments, the thruster can operate with propellant A to produce high thrust at moderate specific impulse, and with propellant B to produce low thrust at high specific impulse. In various embodiments, the use of different propellants may enable the possibility of operating at different specific impulses.

As introduced above, an accelerator electrode may be utilized to produce more thrust and operations at higher value of specific impulses. In some embodiments, the extractor electrodes may also focus the beam, benefiting the performance of the system in two ways. Firstly, if the extractor orifices have the right aperture, the fraction of the beam intercepted by the electrodes may be minimal or null, reducing thus the risk of shorting the electrodes with accumulated propellant in the surfaces and therefore increasing the lifetime of the thruster. Secondly, most of the kinetic energy of the particles emitted may be axial kinetic energy, which may be useful and produce thrust. Typically, radial velocity does not produce thrust since it cancels due to axisymmetry, in other words, the loss of efficiency due to beam divergence may be reduced.

FIG. 25 and FIG. 26 show schematics of two different configurations of the electrospray sources with an accelerator electrode. A schematic diagram illustrating a process for the addition of an accelerator electrode in accordance with an embodiment of the invention is shown FIG. 25. The electrospray source 2500 may include an accelerator 2502, insulator 2504 (e.g., insulating glass), extractor 2506, sealer 2508 (e.g., a sealing glass), emitter array 2510, and a line 2512 (e.g., a silica line) that connects to a propellant reservoir. Another schematic diagram illustrating a process for the addition of an accelerator electrode in accordance with an embodiment of the invention is shown in FIG. 26. The electrospray source 2600 may include an accelerator 2602, a first insulator 2604 (e.g., insulating glass), extractor 2606, a second insulator 2608, emitter array 2610, a sealing glass 2612, and line 2614 (e.g., a silica line) to a propellant reservoir.

The current embodiments may be incorporated into a propulsion system capable for space operation. Such propulsion system may integrate in a compact module the micromachined electrospray source described herein, a power processing unit, and a propellant storage and delivery system comprising various components such as, but not limited to, valves, propellant reservoir, and propellant lines.

Although specific results and considerations are discussed above with respect to FIG. 19A-FIG. 26, any of the results and considerations as appropriate to the requirements of a specific application can be utilized in accordance with embodiments of the invention. While the above description contains many specific embodiments of the invention, these should not be construed as limitations on the scope of the invention, but rather as an example of one embodiment thereof. It is therefore to be understood that the present invention may be practiced otherwise than specifically described, without departing from the scope and spirit of the present invention. Thus, embodiments of the present invention should be considered in all respects as illustrative and not restrictive.

1. A fabrication method for an emitter electrode of an electrospray thruster configured to provide electrostatic acceleration of charged droplets and ions produced by electrospraying a liquid propellant, the method comprising:
etching at least one microfluidic channel on a backside of a wafer, wherein the at least one microfluidic channel provides hydraulic impedance to the flow of the liquid propellant;
etching an emitter array on a front side of the wafer, wherein the emitter array comprises at least one emitter:
wherein the liquid propellant reaches a tip of the at least one emitter through an inner channel etched through the at least one emitter; and
wherein each channel of the at least one microfluidic channel feeds liquid propellant to the at least one emitter of the emitter array via a hole communicating the at least one microfluidic channel with the inner channel of the at least one emitter.

2. The method of claim 1, wherein the wafer is a double-polished silicon wafer.

3. The method of claim 1 further comprising patterning the at least one microfluidic channel on the backside of the wafer using a photoresist prior to etching the at least one microfluidic channel.

4. The method of claim 3, wherein the at least one microfluidic channel is etched using timed DRIE and stripping the photoresist.

5. The method of claim 4 further comprising providing SiO₂ on the backside of the wafer.

6. The method of claim 5, wherein the SiO₂ is provided on the backside of the wafer by growing the SiO₂ via thermal oxidation.

7. The method of claim 5, wherein the SiO₂ is provided on the backside of the wafer by depositing the SiO₂ with PECVD.

8. The method of claim 1 further comprising providing SiO₂ on the front side of the wafer.

9. The method of claim 8, wherein the SiO₂ is provided on the front side of the wafer by depositing the SiO₂ with PECVD.

10. The method of claim 8 further comprising etching the SiO₂ on the front side of the wafer using a lithography mask, in order to create a SiO₂ mask for patterning the well and emitter geometry on the front side of the wafer.

11. The method of claim 10, wherein the well and the emitter geometry on the front side of the wafer are aligned with microchannel ends of the at least one microfluidic channel on the backside of the wafer.

12. The method of claim 10, wherein the well and the inner channels of the at least one emitter are etched on the Silicon wafer using a DRIE process.

13. The method of claim 12, wherein the inner channels of the at least one emitter are partially etched through the Silicon wafer using a lithography mask laid on the SiO₂ mask.

14. The method of claim 12, wherein the well and the inner channels of the at least one emitter are etched using the SiO₂ mask and a DRIE process.

15. The method of claim 12 further comprising connecting the well and emitter inner holes to the at least one microfluidic channel using a DRIE process.

16. The method of claim 12 further comprising shaping at least one emitter tip.

17. The method of claim 16, wherein the at least one emitter tip is shaped by the etching of the well and emitter geometry using XF₂ dry etching.

18. The method of claim 16, wherein the at least one emitter tip is shaped by the etching of the well and emitter geometry using wet etching with hydrofluoric acid, nitric acid, and acetic acid.

19. The method of claim 18, wherein the at least one emitter is coated with a noble metal to eliminate clogging of the at least one emitter by byproducts resulting from electrospraying the liquid propellant.

20. The method of claim 1 further comprising removal of SiO₂ using a buffered oxide etch.

21. The method of claim 1, wherein the at least one emitter is coated with a noble metal to eliminate clogging of the at least one emitter by byproducts resulting from electrospraying the liquid propellant.

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)
